(19) United States
(12) Patent Application Publication
(10) Pub. No.: US 2008/0090320 A1
(43) Pub. Date: Apr. 17, 2008

(54) Self sealed MEMS device

(76) Inventor: John Heck, Berkeley, CA (US)

Correspondence Address: INTEL CORPORATION;c/o INTELLEVATE, LLC, P.O. BOX 52050, MINNEAPOLIS, MN, 55402, US

(21) Appl. No.: 11/582,700

(22) Filed: Oct. 17, 2006

(51) Int. Cl. H01L 21/00

(52) U.S. Cl. 438/52

(57) ABSTRACT

An in-situ package comprises a hermetic enclosure (or “shell”) that may be formed by deposition of a material to form a cap structure. The cap structure may be left open at one end to allow introduction of an etchant to remove sacrificial material used in MEMS device fabrication. After removal, a stamp may be used to stamp the etch tunnel shut forming a compression seal to enclose the MEMS device inside a hermetic gaseous or vacuum cavity.

### FIELD OF THE INVENTION

Embodiments of the present invention are directed to micro-electromechanical systems (MEMS) packaging and, more particularly, to techniques for packaging MEMS devices.

### BACKGROUND INFORMATION

In some cases, MEMS components such as varactors, switches and resonators need to be packaged in a hermetic environment. For example, with radio frequency (RF) MEMS components, there may be a particular need for hermetic packaging. Such packaging protects the MEMS components from contaminants that may be introduced from the outside environment.

Conventionally, two approaches have been utilized for hermetic packaging of MEMS components. Ceramic packages with cavities that may be sealed are used often in the defense industry. This approach, while reliable, may be cost prohibitive for many commercial applications.

A second approach is to use a glass frit to bond a wafer containing the MEMS components to a cover. However, this technique requires high temperature bonding that may not be suitable for all components utilized in some MEMS applications. In some cases, the glass frit occupies a large area that increases the size of the resulting product and therefore increases its costs. In some cases, the glass frit bonding technology uses wire bonds for electrical connections that may not be adequate in some applications, such as high frequency applications.

### BRIEF DESCRIPTION OF THE DRAWINGS

FIGS. 1-6 comprise process diagrams illustrating stamp-sealing a MEMS device in-situ, where:

FIG. 1 is a diagram of a MEMS switch being formed on a wafer;

FIG. 2 is a diagram including a sacrificial layer over the MEMS switch;

FIG. 3 is a diagram including a malleable cap over the MEMS device providing for an etch tunnel;

FIG. 4 is a diagram of the MEMS device after removal of the sacrificial material;

FIG. 5 is a diagram of the MEMS device as shown in FIG. 4 including a stamp wafer;

FIG. 6 is a diagram of the MEMS device after stamp sealing the MEMS device to form a hermetic enclosure;

FIG. 7 is diagram of a MEMS device in a hermetic enclosure with a cap comprising a combination of metal and insulative materials; and

FIG. 8 comprises before and after shots of a MEMS device(s) formed on a wafer sealed according to embodiments of the invention.

### DETAILED DESCRIPTION

According to embodiments of the invention, a self-package (or in-situ package) is realized for a MEMS device wherein the sealing may be accomplished via a stamping process. The in-situ package comprises a hermetic enclosure (or “shell”) that may be formed by deposition of a material to form a cap structure. The material forming the shell may be malleable thus accommodating a stamping process. Once stamped, a shell is formed to enclose a sensitive device inside gaseous or vacuum cavity.

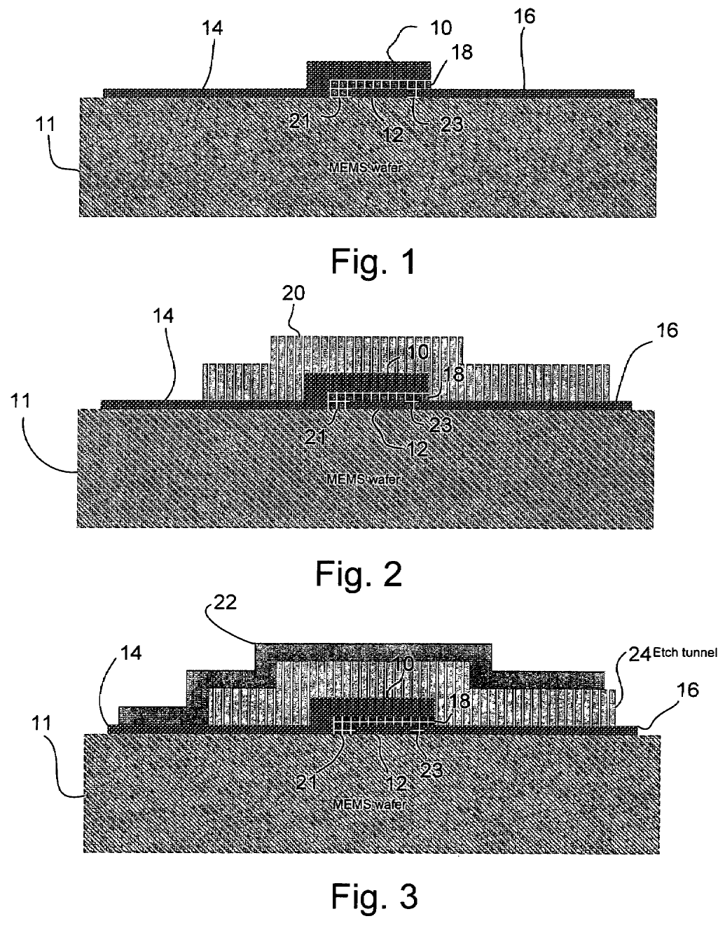

Referring now to FIG. 1, one embodiment of the invention comprises, for example, a self packaging MEMS switch. While embodiments may work with many MEMS devices, for illustrative purposes a MEMS switch is shown. A microelectromechanical system (MEMS) is a microdevice that integrates mechanical and electrical elements on a common substrate using microfabrication technology. The electrical elements are typically formed using known integrated circuit fabrication techniques. The mechanical elements are typically fabricated using lithographic and other related processes to perform micromachining, wherein portions of a substrate (e.g., silicon wafer) are selectively etched away or added to with new materials and structural layers. MEMS devices include actuators, sensors, switches, accelerometers, and modulators, to name a few.

A simple MEMS switch may comprise cantilevered beam 10 over an actuation plate 12 formed on a wafer 11. The cantilevered beam 10 may be connected at one end to an input signal line 14. When the actuation plate 12 is energized, the cantilevered beam 10 is pulled downward to make contact with an output signal line 16 thus closing the switch connecting the input signal line 14 to the output signal line 16. A first sacrificial layer 18 may be used to form the space between the cantilevered beam 10 and the actuation plate 12.

The input line 14 and output line 16 may be formed from a single electrically conductive layer comprising, for example, polysilicon or metal such as gold or aluminum. In an example embodiment, the input and output lines, 14 and 16, may have a thickness ranging from a few thousand angstroms up to about a micron. The conductive layer is then selectively etched to form isolation regions 21 and 23 isolating the actuation plate 12.

As shown in FIG. 2, an additional sacrificial layer 20 may be deposited over the input and output signal lines, 14 and 16, and the cantilevered beam 10. The additional sacrificial layer 20 may be a metal, such as copper, or photoresist, or oxide.

In FIG. 3, a structural shell or cap 22 may be deposited over the additional sacrificial layer 20. The cap 22 is preferably formed from a malleable material, such as gold. Other materials that may be used for the cap 22 may include platinum, aluminum or other metals. Alternatively, a plastic or polymer material may be used in a similar way. The cap 22 may extend over the input signal line 14 and over the additional sacrificial layer 22, generally taking the shape of the sacrificial layer 20. As shown, the cap 22 terminates on top of the sacrificial layer 20 but may not extend down to the output signal line 16. In this manner an opening is left such that etch tunnels 24 are formed around the perimeter of the shell or cap 22. The MEMS device may be released by introduction of an etchant, which enters the shell through the tunnels 24.

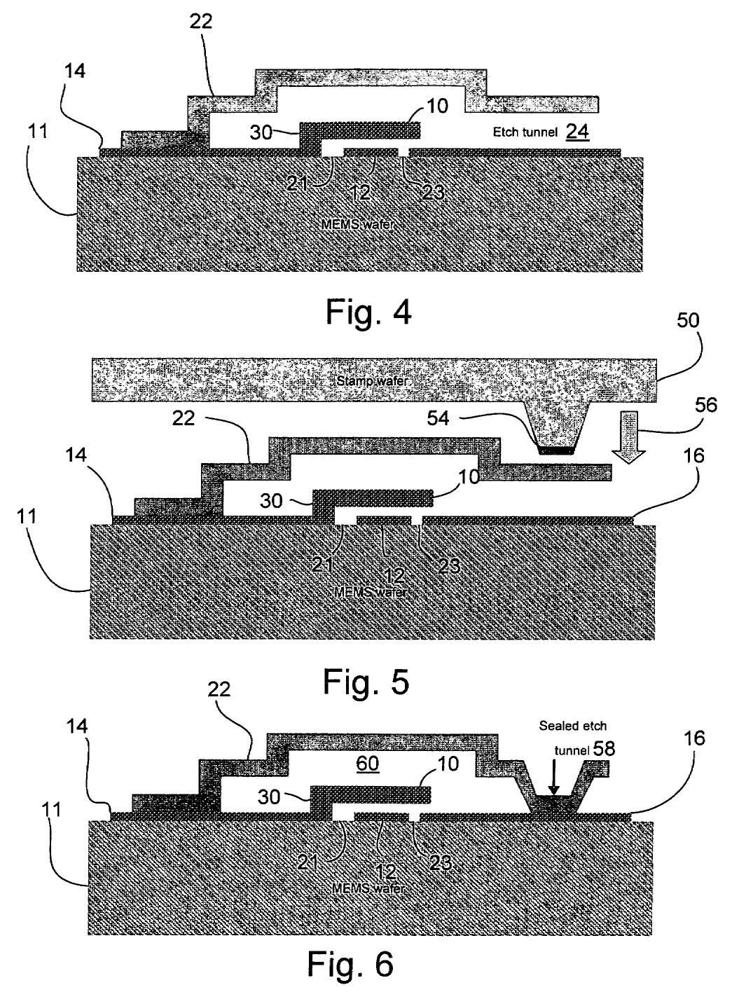

As shown in FIG. 4, the MEMS device may be released by immersion or introduction of an etchant or solvent solution, which enters the shell 22 through the tunnels 24. Likewise, the by-products of the reaction that dissolves the sacrificial layers 18 and 20 may exit via the etch tunnels 24. The result is the formation of a shaped cantilevered beam 10 that is fixed at one end to the input line 14 by anchor portion 30.

Referring now to FIG. 5, according to embodiments of the invention a stamp wafer 50 may be positioned over the cap 22. The stamp 50 may be a similar size and shape to the MEMS wafer 11, such as a 150 mm circular shape, or it may be a small die, such as a 10×10 mm square. In either case, the stamp 50 has one or more raised crimping members 54 which are perpendicular to the etch tunnels 24. The crimping member 54 is shown having a trapezoidal perimeter tapering to a narrower width at the bottom end. Of course other shapes may be suitable as well.

The stamp wafer 50 does not form any kind of bond with the MEMS wafer 11, but when moved in a downward direction as illustrated by arrow 56, makes contact with the cap 22 to thus compress the tunnel 24 such that the cap 22 forms a hermetic seal 58 enclosing the MEMS device as shown in FIG. 6. During stamping, the area may be heated to moderate temperatures to ensure a good seal. The stamp wafer 50 may be a textured silicon wafer coated with nitride, for example and, after stamping may be removed forming no part of the final device. Prior to stamping all air may be removed thus creating a vacuum in the space 60 within the hermetic enclosure between the cap 22 and the MEMS device or filled with an inert gas such as argon or nitrogen.

Typical approaches to self-packaging methods generally require the deposition, lithography, and etching of a sealing layer. In contrast, embodiments of the present invention may have numerous advantages over such approaches. Stamp-sealing as described herein may save significant cost by eliminating the processing steps associated with depositing, patterning, and etching a sealing material. Further, the stamp wafer 50 may be reused many times, for cost reduction. Unlike traditional approaches, the temperature of the stamp-sealing process may be considerably appreciably lower as compared to methods such as solder-sealing. The temperature range can be between room temperature and 350-400° C., although the preferred temperature is 200° C. since it does not affect the MEMS device, yet it ensures the cap 22 material at the etch tunnel 24 (e.g. gold) can be easily compressed and sealed. In addition, just the stamp wafer 50 may be heated, or both wafers 11 and 50 may be heated together.

In addition, the environment 60 inside the stamp-sealed shell 22 can be arbitrarily chosen, since it depends only on the environment inside the bonding tool. In contrast, shells sealed by deposition contain the same environment that is present in the deposition chamber (for example, if nitride is the deposited sealing material, the gaseous precursors of nitride would be present inside the sealed shell.

As previously discussed, the cap 22 material may be malleable such as gold to facilitate stamping. In some applications such as radio frequency (RF) MEMS, metals may not be the optimum material for the shell 22 since they may introduce additional capacitance to the device. In such cases, the cap 22 or at least a portion of the cap 22 may be made of an insulator such as nitride while the tunnels are still made of a malleable material such as gold.

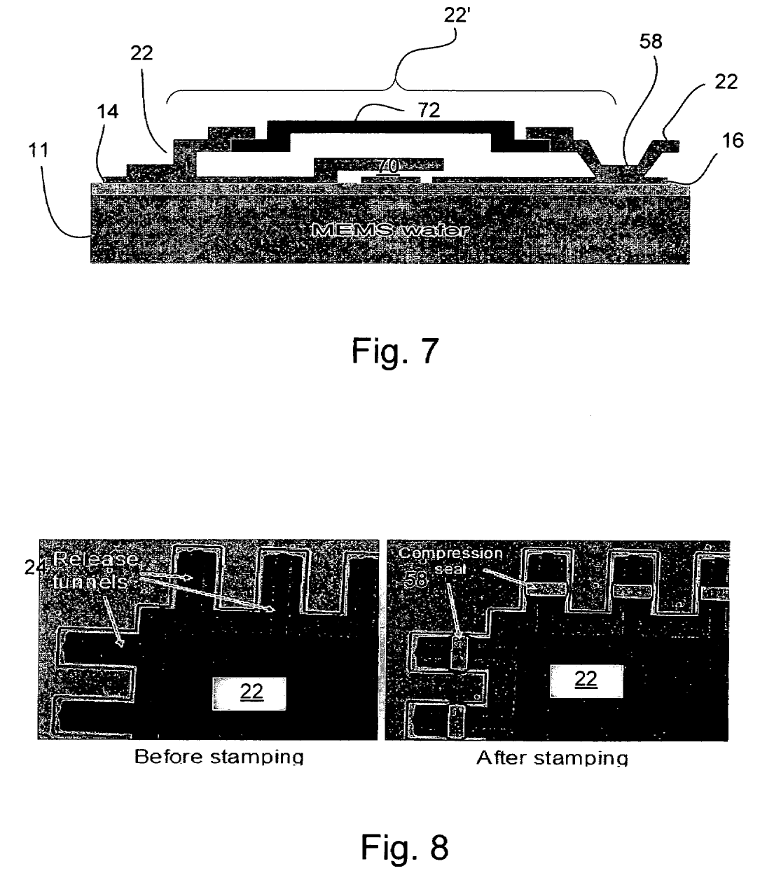

This is illustrated in FIG. 7. As shown, the MEMS device 70 may be formed substantially as before. However, the cap 22′ may be segmented with each segment made of a different material. The top cap segment 72 over the MEMS device 70 may have electrical insulative properties such as nitride. Either end 22 of the of the cap 22′ may be a malleable metal, such as gold in the previous Figures.

FIG. 8 demonstrates before and after shots of a MEMS device stamp sealed according to embodiments. Before stamping the release or etch tunnels 58 are shown intact, thus allowing an etchant to enter under the cap 22 and liberate sacrificial material used in the MEMS fabrication process. After stamping the release or etch tunnels 24 are stamped thus sealing the etch tunnel with a compression seal 58 to hermetically seal the MEMS device under the cap 22.

Stamp-sealed in-situ packages for MEMS offer a significant reduction in form factor, and can be implemented simply at very low cost. This method may be used to package for many types of MEMS devices.

The above description of illustrated embodiments of the invention, including what is described in the Abstract, is not intended to be exhaustive or to limit the embodiments to the precise forms disclosed. While specific embodiments of, and examples for, the invention are described herein for illustrative purposes, various equivalent modifications are possible, as those skilled in the relevant art will recognize. These modifications can be made to embodiments of the invention in light of the above detailed description.

The terms used in the following claims should not be construed to limit the invention to the specific embodiments disclosed in the specification. Rather, the following claims are to be construed in accordance with established doctrines of claim interpretation.

What is claimed is:

1. An apparatus comprising:
a micro-electromechanical system (MEMS) device formed on a wafer;
a cap comprising a malleable material over the MEMS device;
an etch tunnel at least at one end of the cap; and
a stamped portion of the etch tunnel forming a compression seal hermetically enclosing the MEMS device.

2. The apparatus as recited in claim 1 wherein the malleable material comprises gold.

3. The apparatus as recited in claim 1 wherein the cap further comprises:
an electrically insulative material over the MEMS device coupled to the malleable material comprising the etch tunnel.

4. The apparatus as recited in claim 3 wherein the electrically insulative material comprises nitride.

5. The apparatus are recited in claim 3 wherein the MEMS device comprises a switch designed to operate at radio frequencies (RF).

6. A method, comprising:
forming a micro-electromechanical system (MEMS) device on a wafer;
forming a sacrificial layer over the MEMS device;
forming a cap over the sacrificial layer, the cap including an etch tunnel at at least one end;
introducing an etchant via the etch tunnel into an area under the cap;
removing the sacrificial layer with the etchant through the etch tunnel;
stamping the etch tunnel to form a compression seal between the cap and wafer enclosing the MEMS device in a hermetic environment.

7. The method as recited in claim 6 further comprising:
heating the etch tunnel during the stamping.

8. The method as recited in claim 6, wherein the cap is formed from a malleable metal.

9. The method as recited in claim 6, further comprising:
forming the cap from a malleable material section and an electrically insulative material section.

10. The method as recited in claim 9 wherein the malleable material comprises gold and the insulative material comprises nitride.

11. The method as recited in claim 7 wherein the heating is approximately 200-350° C.

12. The method as recited in claim 6 wherein the stamping comprises:
moving a stamp wafer in a direction generally perpendicular to the etch tunnel to compress the etch tunnel.

13. The method as recited in claim 12 wherein the stamp wafer comprises a crimping member having a trapezoidally shaped perimeter.

14. The method as recited in claim 6 wherein the stamping is performed in a vacuum.

15. The method as recited in claim 6 wherein the stamping is performed in an inert gaseous atmosphere.

16. A system, comprising:
a wafer comprising a micro-electromechanical system (MEMS) switch having an input line to be connected to an output line when a cantilevered arm is moved in response to an electrical signal to an actuation plate under the cantilevered arm;
a cap comprising a malleable material over the MEMS switch;
an etch tunnel formed at least at one end of the cap;
an area between the cap and the MEMS switch comprising a hermetic atmosphere;
a stamped portion of the etch tunnel forming a compression seal with the wafer, at least one of the input line and output lines extending outside of the compression seal.

17. The system as recited in claim 17 wherein the malleable material comprises gold.

18. The system as recited in claim 16 wherein the cap comprises at least two sections including an insulative section over the MEMS switch and a malleable metal section forming the etch tunnel.

19. The system as recited in claim 18 wherein the insulative section comprises nitride.

20. The system as recited in claim 16 wherein the hermetic atmosphere comprises one of a vacuum and an inert gas.
